(19) United States
(12) Patent Application Publication
(10) Pub. No.: US 2009/0325393 A1
(43) Pub. Date: Dec. 31, 2009

(54) HEAT TREATMENT METHOD AND HEAT TREATMENT APPARATUS

(75) Inventors: Hidenori Miyoshi, Yamanashi (JP); Masaki Narushima, Yamanashi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Minato-ku ,Tokyo (JP)

(21) Appl. No.: 12/375,681

(22) PCT Filed: Jul. 18, 2007
(86) PCT No.: PCT/JP2007/064201

§ 371 Date: Jan. 30, 2009

(30) Foreign Application Priority Data
Jul. 31, 2006 (JP) 2006-208727

(51) Int. Cl. H01L 21/26; F24C 1/00

(52) U.S. Cl. 438/795; 126/58; 257/E21.328

(57) ABSTRACT

Disclosed is a heat treatment method including a step of placing a wafer W provided with a low-k film and a metal layer in a heat treatment furnace 41, a step of supplying gaseous acetic anhydride into the heat treatment furnace 41, while controlling the flow rate using a mass flow controller 44d, and a step of heating the wafer W in the heat treatment furnace 41 supplied with gaseous acetic anhydride by using a heater 41b provided in the heat treatment furnace 41.

### FIELD OF THE INVENTION

The present invention relates to a heat treatment method and a heat treatment apparatus for performing a heat treatment on a substrate such as a semiconductor substrate having an interlayer insulating film of a low dielectric constant (low-k film) and/or a metal film of, e.g., copper (Cu).

### BACKGROUND OF THE INVENTION

Recently, it is required to reduce capacitance between lines and improve conductivity of lines and electromigration tolerance to meet demands for a high speed semiconductor device, miniaturization of an interconnection pattern and high integration. A Cu multilayer interconnection technique, in which copper (Cu) having high conductivity and excellent electromigration tolerance is used as an interconnection material and a low dielectric constant (low-k) material is used in an interlayer insulating film, has been given attention as a technique in response to the requirements.

The interlayer insulating film made of a low dielectric constant material (low-k film) is formed on a surface of a semiconductor wafer by employing a spin on dielectric (SOD) method or a chemical vapor deposition (CVD) method. In the SOD method, a coating solution is supplied to the surface of the semiconductor wafer and the coating solution is spread by rotating the semiconductor wafer, thereby forming the low-k film. In the CVD method, a source gas is supplied to the surface of the semiconductor wafer and products are deposited by decomposition or composition through chemical reactions, thereby forming the low-k film.

In a case in which the low-k film is formed by the SOD method, the heat treatment is performed on the semiconductor wafer after the low-k film has been formed to relieve internal stress in the low-k film and to ensure its mechanical strength. Further, even in a case in which the low-k film is formed by the CVD method, the heat treatment is occasionally required for a certain selected low-k material. The heat treatment is generally performed in a vacuum or an atmosphere of a nonreactive gas such as a nitrogen gas (see, e.g., Japanese Laid-open Publication No. 2000-272915). However, it is very difficult to make a complete vacuum or nonreactive gas atmosphere, and impurities such as oxygen can be easily contained in the atmosphere. Accordingly, in these methods, there is a worrisome possibility that the low-k film may be oxidized and degraded due to oxygen contained in the atmosphere.

Meanwhile, a Cu line is formed by forming a via hole in a semiconductor wafer or a low-k film, forming a Cu seed layer on the semiconductor wafer or the low-k film including the via hole, and performing Cu plating. After the Cu line is formed, in the same way as in the low-k film, a heat treatment is performed in a vacuum or an atmosphere of a nonreactive gas such as a nitrogen gas for the purpose of stabilizing electrical resistance of lines at a low value by enlarging Cu crystal grains (see, e.g., Japanese Laid-open Publication No. 2002-285379). However, since Cu is easily oxidized to form oxide on the Cu line, in the heat treatment, there is a worrisome possibility that a metal film is oxidized due to oxygen contained in the atmosphere. In Cu multilayer interconnection with a via contact between upper and lower lines, if oxide exists on the surface of the Cu line, a good contact cannot be obtained.

### SUMMARY OF THE INVENTION

It is an object of the present invention to provide a heat treatment method and a heat treatment apparatus capable of surely preventing oxidation of an interlayer insulating film of a low dielectric constant and/or a metal film.

It is another object of the present invention to provide a computer-readable storage medium storing a program for executing the heat treatment method.

In accordance with a first aspect of the present invention, there is provided a heat treatment method comprising: placing a substrate having an interlayer insulating film of a low dielectric constant (low-k film) and/or a metal film in a processing chamber; supplying the processing chamber with a reducing gaseous organic compound containing at least one of carboxylic acid anhydride, ester, organic acid ammonium salt, organic acid amine salt, organic acid amide, organic acid hydrazide, organic acid metal complex, and organic acid metal salt while controlling its flow rate; and heating the substrate in the processing chamber supplied with the gaseous organic compound.

In the first aspect of the present invention, a film containing copper (Cu) may be used as the metal film.

In accordance with a second aspect of the present invention, there is provided a heat treatment apparatus for performing a heat treatment on a substrate having an interlayer insulating film of a low dielectric constant (low-k film) and/or a metal film, the heat treatment apparatus comprising: a processing chamber for accommodating a substrate therein; an organic compound supply unit for supplying the processing chamber with a reducing gaseous organic compound containing at least one of carboxylic acid anhydride, ester, organic acid ammonium salt, organic acid amine salt, organic acid amide, organic acid hydrazide, organic acid metal complex, and organic acid metal salt while controlling its flow rate; and a heating unit for heating the substrate in the processing chamber, wherein the substrate is heated in the processing chamber in a state where the reducing gaseous organic compound is supplied to the processing chamber.

In accordance with a third aspect of the present invention, there is provided a storage medium which is operated on a computer and stores a program for controlling a heat treatment apparatus, wherein the program controls the heat treatment apparatus to perform a heat treatment method including: placing a substrate having an interlayer insulating film of a low dielectric constant (low-k film) and/or a metal film in a processing chamber; supplying the processing chamber with a reducing gaseous organic compound containing at least one of carboxylic acid anhydride, ester, organic acid ammonium salt, organic acid amine salt, organic acid amide, organic acid hydrazide, organic acid metal complex, and organic acid metal salt while controlling its flow rate; and heating the substrate in the processing chamber supplied with the gaseous organic compound.

As a technique for preventing oxidation of the low-k film, the applicant of the present invention has proposed a technique for performing a heat treatment on a substrate having a low-k film in an atmosphere of alcohol, aldehyde and/or carboxylic acid such as formic acid having excellent reducibility (Japanese Patent Application No. 2006-152369). However, the formic acid or the like tends to undergo conversion of monomers to polymers and when there is variation in external factors such as pressure or temperature, a composition ratio of monomers and polymers (dimers) is largely changed by a polymerization or dissociation reaction. Accordingly, in this technique, when the supply of a formic acid gas (or vapor) is performed while controlling its flow rate by using a flow rate controller, variation of a composition ratio influences a conversion factor to cause an error in an actual flow rate and a flow rate set by the flow rate controller. As a result, it is difficult to ensure process reproducibility.

Therefore, the present invention is devised to achieve the above objects and solve a problem of process reproducibility.

In accordance with the present invention, a substrate having an interlayer insulating film of a low dielectric constant and/or a metal film is accommodated in a processing chamber. An organic compound including at least one of carboxylic acid anhydride, ester, organic acid ammonium salt, organic acid amine salt, organic acid amide, organic acid hydrazide, organic acid metal complex, and organic acid metal salt having excellent reducibility without polymerization which occasionally occurs in aldehyde or carboxylic acid is supplied into the processing chamber while controlling its flow rate. Then, the substrate is heated in an atmosphere of the organic compound. Accordingly, it is possible to surely prevent oxidation of an interlayer insulating film of a low dielectric constant and/or a metal film by a reduction reaction of the organic compound. Further, it is possible to prevent occurrence of an error in an actual flow rate and a flow rate set by controlling a flow rate of the organic compound supplied into the processing chamber, thereby sufficiently ensuring process reproducibility.

### BRIEF DESCRIPTION OF THE DRAWINGS

FIG. 1 schematically shows a plan view of a wafer processing system including a heat treatment apparatus capable of performing a heat treatment method in accordance with the present invention.

FIG. 2 schematically shows a cross sectional view of the heat treatment apparatus.

FIG. 3A illustrates a cross sectional view for explaining a damascene process.

FIG. 3B illustrates a cross sectional view for explaining the damascene process.

FIG. 4 schematically shows a cross sectional view of another heat treatment apparatus capable of performing the heat treatment method in accordance with the present invention.

FIG. 5 schematically shows a cross sectional view of still another heat treatment apparatus capable of performing the heat treatment method in accordance with the present invention.

### DETAILED DESCRIPTION OF THE EMBODIMENTS

Hereinafter, embodiments of the present invention will be described in detail with reference to the accompanying drawings which form a part hereof.

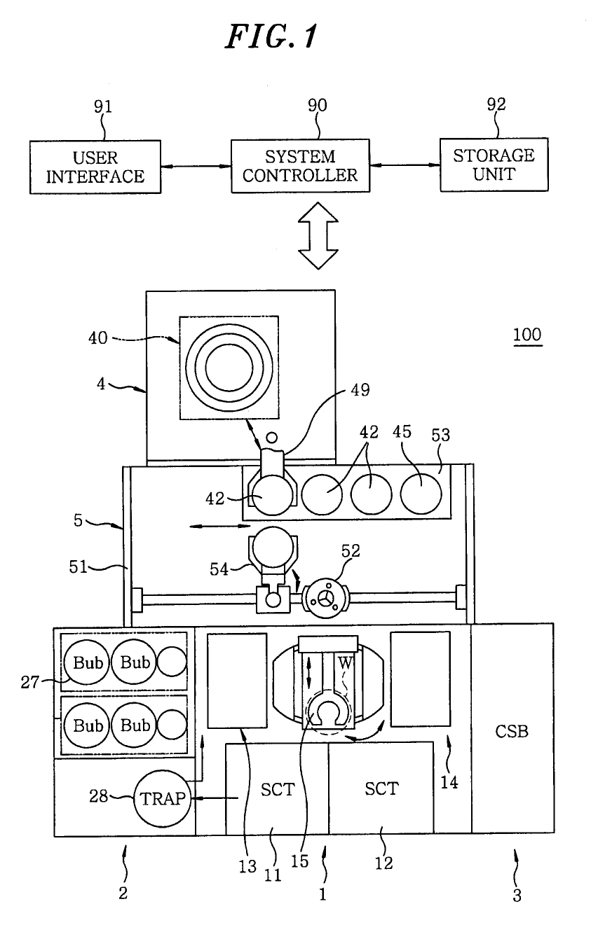

FIG. 1 schematically shows a plan view of a wafer processing system including a heat treatment apparatus capable of performing a heat treatment method in accordance with the present invention.

The wafer processing system 100 includes a process station 1 having multiple units for performing a specific process on a wafer W serving as a semiconductor substrate, a side cabinet 2 and a carrier station (CSB) 3 provided at opposite sides (left and right sides in FIG. 1) of the process station 1, a heat treatment unit 4 provided at a rear side (upper side in FIG. 1) of the process station 1 to perform a heat treatment on the wafer W, and an interface station 5 provided between the process station 1 and the heat treatment unit 4 to perform a delivery of the wafer W therebetween.

The process station 1 includes coating process units (SCT) 11 and 12, processing unit sets 13 and 14 each having a plurality of processing units stacked in multiple levels, and a transfer arm 15 for transferring a semiconductor wafer (substrate) W between the coating process units (SCT) 11 and 12, the processing unit sets 13 and 14 and the interface station 5. The transfer arm 15 is disposed in an approximately central portion of the process station 1. The processing unit sets 13 and 14 are disposed at sides of the transfer arm 15 adjacent to the side cabinet 2 and the carrier station (CSB) 3, respectively. The coating process units (SCT) 11 and 12 are disposed right in front of the processing unit sets 13 and 14. A coating solution storage part (not shown) for storing a coating solution or the like used in the coating process units (SCT) 11 and 12 is disposed, for example, under the coating process units (SCT) 11 and 12.

The coating process units (SCT) 11 and 12 are configured such that a specific coating solution for a low-k film, a hard mask layer or the like is supplied to a surface of the wafer W held by, for example, a spin chuck, and the spin chuck is rotated to spread the coating solution on the surface of the wafer W, thereby forming a coating film such as a low-k film or a hard mask layer. The processing unit set 13 includes a low temperature hot plate unit which bakes the wafer W at a low temperature, an aging unit which gelates the coating film such as a low-k film formed on the wafer W and the like, the units being vertically stacked. The heat treatment unit is configured to heat the wafer W having the coating film under a reducing organic compound atmosphere. The processing unit set 14 includes a delivery unit for performing a delivery of the wafer W to/from the carrier station (CSB) 3, a high temperature hot plate unit which bakes the wafer W at a high temperature, and a cooling plate unit for cooling the wafer W, the units being vertically stacked. The transfer arm 15 can move up and down, rotate horizontally and move forward and backward so as to access the coating process units (SCT) 11 and 12 and the respective processing units of the processing unit sets 13 and 14.

The side cabinet 2 includes bubblers (Bub) 27 used in the processing unit sets 13 and 14 and the like, and a trap (TRAP) 28 for cleaning a gas exhaust gas discharged from each unit. Further, a liquid chemical storage part for storing pure water or an organic compound, e.g., a processing solution such as acetic acid anhydride, and a drain for discharging waste of a used processing solution are disposed, for example, under the bubblers (Bub) 27.

The carrier station (CSB) 3 includes a mounting table for mounting a cassette accommodating the wafer W, and a transfer mechanism for transferring the wafer W between the cassette mounted on the mounting table and the delivery unit disposed in the process station 1.

The interface station 5 includes, in an approximately sealed box 51, a positioning mechanism 52 which receives the wafer W transferred from the transfer arm 15 and determines its position, a boat liner 53 mounted with wafer boats 42 and a dummy wafer boat 45 for accommodating a plurality of wafers W in a heat treatment furnace 41 of a heat treatment apparatus 40 to be described later, a transfer mechanism 54 for transferring the wafer W between the positioning mechanism 52 and the wafer boat 42 (or the dummy wafer boat 45). The positioning mechanism 52 and the transfer mechanism 54 are provided at a front side (side of the process station 1) of the interface station 5. The boat liner 53 is mounted with a plurality of, for example, three, wafer boats 42 and one dummy wafer boat 45 and provided at a rear side (side of the heat treatment unit 4) of the interface station 5 to be movable along a rear surface of the interface station 5.

The heat treatment unit 4 includes the heat treatment apparatus 40 for performing a heat treatment on the wafer W and a transfer body 49 for transferring the wafer boat 42 (or the dummy wafer boat 45) between the heat treatment apparatus 40 and the boat liner 53. The heat treatment apparatus 40 is a so-called batch type heat treatment apparatus which simultaneously performs a heat treatment on a plurality of wafers W accommodated in the wafer boats 42, and heats the wafers W in an atmosphere of carboxylic acid anhydride, for example, acetic acid anhydride. The heat treatment apparatus 40 will be described in detail later.

Each component, for example, each processing unit and each processing apparatus of the wafer processing system 100 is connected to and controlled by a system controller 90 having a microprocessor (computer). The system controller 90 is connected to a user interface 91 including a keyboard for inputting commands, a display for displaying an operation status of the wafer processing system 100 and the like such that an operator manages the wafer processing system 100. The system controller 90 is also connected to a storage unit 92 which stores recipes including control programs for performing various processes under control of the system controller 90 in the SOD system 100, process conditions or the like. Further, if necessary, a certain recipe may be retrieved from the storage unit 92 in accordance with the commands inputted through the user interface 91 and executed in the system controller 90 such that a desired process is performed in the wafer processing system 100 under control of the system controller 90. Further, the recipes may be stored in a computer-readable storage medium such as a CD-ROM, a hard disk and a flash memory. Further, the recipes may be appropriately transmitted from another device through, for example, a dedicated line.

In the wafer processing system 100 having the above configuration, when a coating film such as a low-k film is formed on the wafer W by employing a silk method and a speed film method, the wafer W is transferred from the carrier station (CSB) 3 in a sequence of the delivery unit→the cooling plate unit→the coating process unit (SCT) 12→the low temperature hot plate unit→the cooling plate unit→the coating process unit (SCT) 11→the low temperature hot plate unit→the high temperature hot plate unit→the heat treatment apparatus 40, and a specific process is performed on the wafer W in each unit. In this case, an adhesion promoter is coated in the coating process unit (SCT) 12, and a coating solution for a low-k film is coated in the coating process unit (SCT) 11. When a coating film such as a low-k film is formed by a fox method, the wafer W is transferred in a sequence of the delivery unit→the cooling plate unit→the coating process unit (SCT) 11→the low temperature hot plate unit→the high temperature hot plate unit→the heat treatment apparatus 40, and a specific process is performed on the wafer W in each unit. Further, the heat treatment apparatus 40 is a batch type apparatus and other units except the heat treatment apparatus 40 are so-called single-wafer units for performing the wafers W one by one. Accordingly, the wafers W which have been processed are sequentially contained in the wafer boat 42 before the treatment of the heat treatment apparatus 40. Then, the wafer boat 42 having a specific number of wafers W is transferred to the heat treatment apparatus 40 and the treatment is performed in the heat treatment apparatus 40. When a coating film such as a low-k film is formed by a sol-gel method, the wafer W is transferred in a sequence of the delivery unit→the cooling plate unit→the coating process unit (SCT) 11→the aging unit→the low temperature hot plate unit→the high temperature hot plate unit, and a specific process is performed on the wafer W in each unit.

When a silk method, a speed film method or a fox method is used, in a final process, a heat treatment is performed in the heat treatment apparatus 40. For example, a hardening process is performed on a coating film such as a low-k film or a hard mask film. As described above, conventionally, the treatment is performed by heating the wafer in a vacuum or an atmosphere of a nonreactive gas such as a nitrogen gas. However, it is difficult to sufficiently suppress degradation (oxidation) of the coating film due to impurities such as oxygen contained in the atmosphere in the conventional method. In order to suppress the oxidation of the coating film, as described above, the wafer may be heated in an atmosphere of alcohol, aldehyde and/or carboxylic acid such as formic acid having excellent reducibility. However, the formic acid or the like may undergo conversion of monomers to polymers or conversion of polymers to monomers due to temperature variation. Accordingly, it is difficult to stably supply the formic acid having a highly variable composition ratio in a gas phase.

Thus, in the embodiment of the present invention, the wafer W is heated in an atmosphere of carboxylic acid anhydride such as acetic acid anhydride having excellent reducibility without polymerization, and the heat treatment, for example, a hardening process, is performed on the coating film such as a low-k film. Accordingly, oxygen in the atmosphere can be efficiently removed by a reduction reaction of the acetic acid anhydride without generating an error in a supply flow rate through a flow rate controller such as a mass flow controller, thereby surely preventing degradation of a low-k film and sufficiently ensuring reproducibility of a process.

Further, when a metal film for, e.g., Cu lines is formed on the wafer W and oxide is formed on the surface of the metal film, the oxide can be removed by a reduction reaction of acetic acid anhydride in the heat treatment in the heat treatment apparatus 40.

The carboxylic acid anhydride such as acetic acid anhydride used in the heat treatment method of the embodiment of the present invention may be represented by R¹—CO—O—CO—R² (R¹, R² is a hydrogen atom, a hydrocarbon group, or a halogen-substituted hydrocarbon group in which at least one hydrogen atom forming a hydrocarbon group is substituted with halogen atom(s)). The hydrocarbon groups may include an alkyl group, an alkenyl group, an alkynyl group and an allyl group. As examples of halogen atoms, there are fluorine, chlorine, bromine and iodine. As examples of carboxylic acid anhydride, there are formic acid anhydride, propionic acid anhydride, acetic formic acid anhydride, butyric acid anhydride, and valeric acid anhydride in addition to acetic acid anhydride. However, since the formic acid anhydride and acetic formic acid anhydride are relatively unstable materials, it is preferable to use materials other than formic acid anhydride and acetic formic acid anhydride.

Further, ester, organic acid ammonium salt, organic acid amine salt, organic acid amide, organic acid hydrazide, organic acid metal complex, and organic acid metal salt provide the same effect as the carboxylic acid anhydride having excellent reducibility without polymerization.

The ester may be represented by R³—COO—R⁴ (R³ is a hydrogen atom, a hydrocarbon group, or a halogen-substituted hydrocarbon group in which at least one hydrogen atom forming a hydrocarbon group is substituted with halogen atom(s), and R⁴ is a hydrocarbon group, or a halogen-substituted hydrocarbon group in which at least one hydrogen atom forming a hydrocarbon group is substituted with halogen atom(s)). Examples of the hydrocarbon group and halogen atoms are the same as the above-mentioned examples. As examples of ester, there are methyl formate, ethyl formate, propyl formate, butyl formate, benzyl formate, methyl acetate, ethyl acetate, propyl acetate, butyl acetate, pentyl acetate, hexyl acetate, octyl acetate, phenyl acetate, benzyl acetate, allyl acetate, propenyl acetate, methyl propionate, ethyl propionate, butyl propionate, pentyl propionate, benzyl propionate, methyl butyrate, ethyl butyrate, pentyl butyrate, butyl butyrate, methyl valerate, and ethyl valerate.

The organic acid ammonium salt and the organic acid amine salt may be represented by R⁵—COO—NR⁶R⁷R⁸R⁹ (R⁵, R⁶, R⁷, R⁸, R⁹ is a hydrogen atom, a hydrocarbon group, or a halogen-substituted hydrocarbon group in which at least one hydrogen atom forming a hydrocarbon group is substituted with halogen atom(s)). Examples of the hydrocarbon group and halogen atoms are the same as the above-mentioned examples. As examples of organic acid ammonium salt and organic acid amine salt, there are organic acid ammonium (R⁵COONH₄), primary amine salt such as organic acid methylamine salt, organic acid ethylamine salt and organic acid t-butylamine salt, secondary amine salt such as organic acid dimethylamine salt, organic acid ethylmethylamine salt and organic acid diethylamine salt, tertiary amine salt such as organic acid trimethylamine salt, organic acid diethylmethylamine salt, organic acid ethyldimethylamine salt and organic acid trimethylamine salt, and quaternary ammonium salt such as organic acid tetramethyl ammonium and organic acid triethylmethyl ammonium.

The organic acid amide may be represented by R¹⁰—CO—NH₂ (R¹⁰ is a hydrogen atom, a hydrocarbon group, or a halogen-substituted hydrocarbon group in which at least one hydrogen atom forming a hydrocarbon group is substituted with halogen atom(s)). Examples of the hydrocarbon group and halogen atoms are the same as the above-mentioned examples. As an example of organic acid amide, there is carboxylic acid amide.

The organic acid hydrazide may be represented by R¹¹—CO—NH—NH₂ (R¹¹ is a hydrogen atom, a hydrocarbon group, or a halogen-substituted hydrocarbon group in which at least one hydrogen atom forming a hydrocarbon group is substituted with halogen atom(s)). Examples of the hydrocarbon group and halogen atoms are the same as the above-mentioned examples. As examples of organic acid forming the organic acid hydrazide, there are formic acid, acetic acid, propionic acid, butyric acid, acetic formic acid and valeric acid.

The metal complex or metal salt may be represented by Mₐ(R¹²COO)_{b} (M is a metal atom, a and b are natural numbers, and R¹² is a hydrogen atom, a hydrocarbon group, or a halogen-substituted hydrocarbon group in which at least one hydrogen atom forming a hydrocarbon group is substituted with halogen atom(s)). Examples of the hydrocarbon group and halogen atoms are the same as the above-mentioned examples. As examples of the metal complex of organic acid or metal salt of organic acid, there are titanium (Ti), ruthenium (Ru), copper (Cu), silicon (Si), cobalt (Co) and aluminum (Al). As examples of the organic acid forming the metal complex of organic acid or metal salt of organic acid, there are formic acid, acetic acid, propionic acid, butyric acid, acetic formic acid and valeric acid. As examples of the metal complex of organic acid or metal salt of organic acid, there are titanium formate, ruthenium formate, copper formate, silicon formate, cobalt formate, and aluminum formate when the organic acid is formic acid; titanium acetate, ruthenium acetate, copper acetate, silicon acetate, cobalt acetate and aluminum acetate when the organic acid is acetic acid; and titanium propionate, ruthenium propionate, copper propionate, silicon propionate, cobalt propionate and aluminum propionate when the organic acid is propionic acid.

Further, a combination of carboxylic acid anhydride, ester, organic acid ammonium salt, organic acid amine salt, organic acid amide, organic acid hydrazide, organic acid metal complex, and organic acid metal salt may be employed.

Materials of the low-k film, to which the heat treatment method in accordance with the present invention is more effectively applied, may include siloxane-based hydrogen-silsesquioxane (HSQ) containing Si, O and H, methyl-silsesquioxane (MSQ) containing Si, C, O and H, FLARE (manufactured by Honeywell Inc.) made of organic polyallylene ether, SILK (manufactured by the Dow Chemical Company) made of polyallylene hydrocarbon, Parylene, BCB, PTFE, fluorinated polyimide, porous MSQ, porous SILK, porous silica and the like. Further, materials of, e.g., a hard mask film in addition to the low-k film, to which the heat treatment method in accordance with the present invention is more effectively applied, may include polybenzoxazole.

Further, the heat treatment method in according to the present invention may be also applied to a case in which, e.g., a low-k film is formed by CVD. In this case, materials of the low-k film, to which the heat treatment method in accordance with the present invention is more effectively applied, may include SiOC-based materials (a methyl group (—CH₃) is introduced into a Si—O bond of SiO₂ and mixed with Si—CH₃) such as Black Diamond (manufactured by Applied Materials Inc.), Coral (manufactured by Novellus Inc.) and Aurora (manufactured by ASM Inc.), SiOF-based materials (fluorine (F) is introduced into SiO₂), CF-based materials using fluorocarbon gas and the like. Further, materials of, e.g., a hard mask film in addition to the low-k film, to which the heat treatment method in accordance with the present invention is more effectively applied, may include the same materials as the above-mentioned materials of the low-k film (having a higher dielectric constant than the low-k film), silicon carbide (SiC), silicon carbonitride (SiCN) and the like.

As described above, materials of the metal film, to which the heat treatment method in accordance with the present invention is more effectively applied, may include Cu (only Cu or a Cu alloy). The Cu alloy may include magnesium (Mg), aluminum (Al), silicon (Si), scandium (Sc), titanium (Ti), vanadium (V), chromium (Cr), manganese (Mn), iron (Fe), cobalt (Co), nickel (Ni), zinc (Zn), gallium (Ga), germanium (Ge), strontium (Sr), yttrium (Y), zirconium (Zr), niobium (Nb), molybdenum (Mo), ruthenium (Ru), rhodium (Rh), palladium (Pd), silver (Ag), indium (In), tin (Sn), antimony (Sb), tantalum (Ta), tungsten (W), rhenium (Re), osmium (Os), iridium (Ir), platinum (Pt), gold (Au), or lead (Pb).

Next, the heat treatment apparatus 40 will be described in detail.

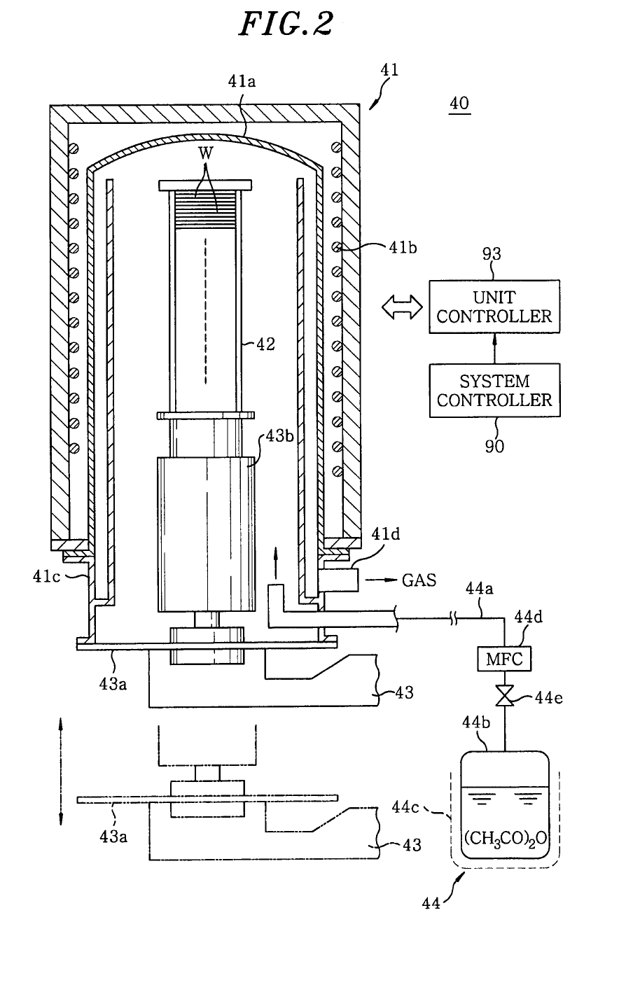

FIG. 2 schematically shows a cross sectional view of the heat treatment apparatus 40.

The heat treatment apparatus 40 includes an approximately cylindrical heat treatment furnace (processing chamber) 41 which has a lower opening and accommodates and heats the wafers W, a wafer boat 42 which supports the wafers W in the heat treatment furnace 41, a boat elevator 43 which elevates the wafer boat 42 such that the wafer boat 42 moves into or out of the heat treatment furnace 41, a processing gas supply unit 44 which supplies acetic acid anhydride as a processing gas into the heat treatment furnace 41.

A process tube 41a made of quartz is formed in the heat treatment furnace 41 in a shape corresponding to the shape of the heat treatment furnace 41. A heater 41b for heating the wafers W is provided at an outer periphery of the process tube 41a to surround the process tube 41a. An annular or cylindrical manifold 41c is provided at a lower end of the process tube 41a. The manifold 41c is connected to a processing gas supply line 44a of the processing gas supply unit 44 to be described later and also connected to a gas exhaust port 41d for evacuation of the heat treatment furnace 41.

The wafer boat 42 is configured to support a plurality of wafers W vertically stacked at specific intervals. A cover part 43a is provided at the boat elevator 43. The cover part 43a is in contact with the manifold 41c to maintain the inside of the process tube 41a in a sealed state. A thermal insulation container 43b is mounted on the cover part 43a.

The processing gas supply unit 44 includes a storage part 44b for storing, e.g., liquid acetic acid anhydride ((CH₃CO)₂O), a heating part 44c such as a heater for heating and vaporizing the acetic acid anhydride of the storage part 44b, a processing gas supply line 44a for supplying an acetic acid anhydride gas (vaporized acetic acid anhydride) produced by heating of the heating part 44c to the heat treatment furnace 41, and a mass flow controller 44d and a valve 44e serving as a flow rate controller for controlling a flow rate of the acetic acid anhydride gas flowing in the processing gas supply line 44a.

The heat treatment apparatus 40 is controlled by a unit controller 93 connected to the system controller 90. Further, if necessary, the system controller 90 may retrieve a certain recipe from the storage unit 92 in accordance with the commands inputted through the user interface 91 to control the unit controller 93.

In the heat treatment apparatus 40 having the above configuration, first, in a state where the boat elevator 43 is moved down, the wafer boat 42 having a plurality of wafers W is loaded into the boat elevator 43 (the thermal insulation container 43b) by using the transfer body 49. Then, the boat elevator 43 is moved up until the cover part 43a is made to be in contact with the manifold 41c, and the wafer boat 42 is received into the heat treatment furnace 41. Then, an acetic acid anhydride gas is supplied to the heat treatment furnace 41 by using the processing gas supply unit 44. Accordingly, oxygen is efficiently removed from the heat treatment furnace 41 by a reduction reaction of acetic acid anhydride. Further, the inside of the heat treatment furnace 41 is maintained under an atmosphere of an acetic acid anhydride gas having a low oxygen density (for example, 50 ppm or less). The supply of the acetic acid anhydride gas is performed while controlling its flow rate through the mass flow controller 44d and the valve 44e. However, since the acetic acid anhydride does not undergo polymerization, an actual flow rate and a flow rate set by the mass flow controller 44d have almost the same value without an error. Thus, it is possible to improve accuracy of the heat treatment and sufficiently ensure process reproducibility.

After the inside of the heat treatment furnace 41 is maintained under an atmosphere of an acetic acid anhydride gas having a low oxygen density, each wafer W is heated while the temperature of the heater 41b is set to be, for example, 200˜400° C. Accordingly, a coating film such as a low-k film, a hard mask film or the like formed on each wafer W is hardened in almost no contact with oxygen, thereby preventing degradation. Further, oxidation of a metal film formed on each wafer W is also prevented. When oxide exists on the surface of the metal film, the oxide is removed. Further, acetic acid anhydride or products such as water and carbon dioxide produced by a reduction reaction of acetic acid anhydride are discharged through the gas exhaust port 41d out of the heat treatment furnace 41.

When the wafers W are completely heated by the heater 41b, the supply of an acetic acid anhydride gas using the processing gas supply unit 44 is stopped. Then, the boat elevator 43 is moved down and the wafer boat 42 is unloaded from the heat treatment furnace 41. Then, the wafer boat 42 is transferred by using the transfer body 49.

Further, when at least one of organic acid ammonium salt, organic acid amine salt, organic acid amide and organic acid hydrazide is used as a processing gas supplied from the processing gas supply unit 44, it is possible to obtain a corrosion suppressing effect of an inner wall of the storage part 44b of the processing gas supply unit 44 and the processing gas supply line 44a and the like.

Next, an application example of the heat treatment using the heat treatment apparatus 40 to a damascene process will be described.

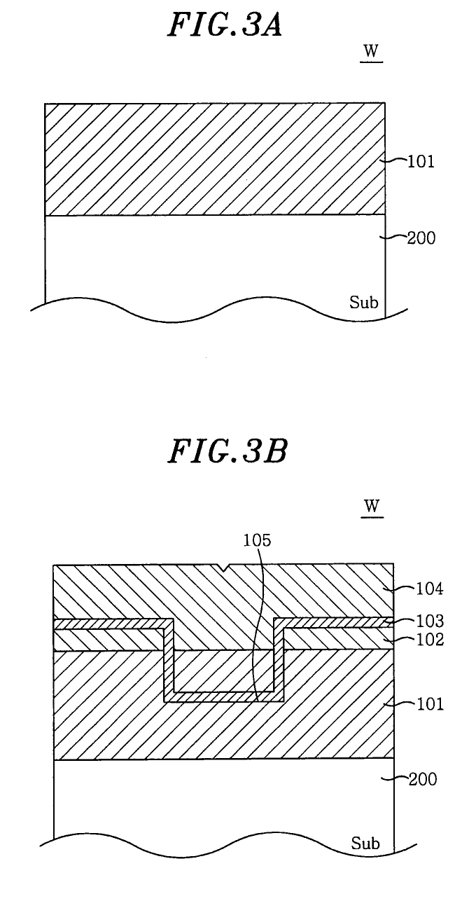

FIGS. 3A and 3B illustrate cross sectional views of a wafer W in a damascene process.

In the damascene process, for example, first, a low-k film 101 is formed as an interlayer insulating film on a Si substrate (Sub) 200 forming the wafer W (see FIG. 3A). The low-k film 101 is formed through the process of the process station 1 of the above-described wafer processing system 100. When the low-k film 101 is formed, a heat treatment is performed on the wafer W in the heat treatment apparatus 40. In this case, the low-k film 101 is prevented from being oxidized and degraded by an oxidation reduction reaction of acetic acid anhydride to thereby have a sufficient strength. Then, a hard mask film 102 is formed on the low-k film 101 through the same process as the process for forming the low-k film 101, and a heat treatment is performed on the wafer W in the heat treatment apparatus 40. In this case, the hard mask film 102 is prevented from being oxidized by an reduction reaction of acetic acid anhydride to thereby have a sufficient strength.

Subsequently, the hard mask film 102 is etched while a resist film (not shown) patterned by a photolithography is used as a mask, and a groove 105 is formed in the low-k film 101 by etching while the resist film and the etched hard mask film 102 are used as a mask. Further, a barrier metal film 103 and a wiring layer 104 made of Cu are sequentially formed on the hard mask film 102 and in the groove 105 (see FIG. 3B). The barrier metal film 103 is formed by sputtering or the like and the wiring layer 104 is formed by a plating method or the like. When the barrier metal film 103 and the wiring layer 104 are formed, the wafer W undergoes the heat treatment in the heat treatment apparatus 40. In this case, the wiring layer 104 undergoes an annealing process without being oxidized by a reduction reaction of acetic acid anhydride.

Then, the surface of the wiring layer 104 is polished by using a CMP method to form a wiring portion of a damascene structure.

Hereinafter, another heat treatment apparatus capable of performing the heat treatment method in accordance with the present invention will be described.

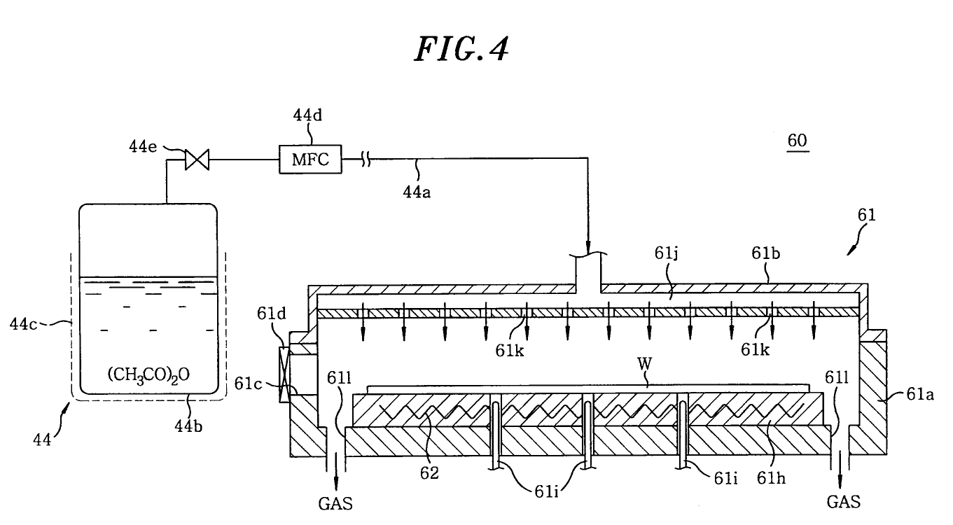

FIG. 4 schematically shows a cross sectional view of another heat treatment apparatus capable of performing the heat treatment method in accordance with the present invention.

A single wafer heat treatment apparatus 60 for performing a heat treatment on wafers W one by one will be described in this embodiment. Further, in the heat treatment apparatus 60, the same parts as those of the heat treatment apparatus 40 are designated by the same reference numerals and the description thereof is omitted. The heat treatment apparatus 60 includes a chamber (processing chamber) 61 capable of accommodating the wafer W, a processing gas supply unit 44 for supplying an acetic acid anhydride gas as a processing gas to the chamber 61, and a heater 62 for heating the wafer W in the chamber 61. Further, the heat treatment apparatus 60 is controlled in the same way as the heat treatment apparatus 40.

The chamber 61 includes an approximately cylindrical or box-shaped chamber main body 61a having an upper opening, and a lid 61b for closing the upper opening of the chamber main body 61a. A loading/unloading port 61c is formed at a sidewall of the chamber main body 61a to load/unload the wafer W to/from the chamber 61. Also, a shutter 61d for opening and closing the loading/unloading port 61c is formed at the sidewall of the chamber main body 61a. The processing gas supply line 44a of the processing gas supply unit 44 is connected to the lid 61b.

A discharge port 611 is formed in the chamber main body 61a, for example, at its bottom portion, to discharge an acetic acid anhydride gas or the like supplied by using the processing gas supply unit 44 out of the chamber 61. Further, a mounting table 61h is disposed in the chamber main body 61a, for example, at its bottom portion, to mount the wafer W thereon. The heater 62 is embedded in the mounting table 61h to heat the wafer W through the mounting table 61h. Supporting pins 61i are provided in the mounting table 61h to be moved up and down such that the supporting pins 61i can be protruded from an upper surface of the mounting table 61h and retracted into the mounting table 61h. When the supporting pins 61i are protruded, a delivery of the wafer W is performed. When the supporting pins 61i are retracted, the wafer W is mounted on the mounting table 61h.

The lid 61b is formed in an approximately cylindrical or box shape having a flat diffusion space 61j therein. Further, the lid 61b has a number of discharge holes 61k on its bottom surface to discharge an acetic acid anhydride gas supplied from the processing gas supply unit 44. The acetic acid anhydride gas is supplied through the upper surface of the lid 61b into the diffusion space 61j from the processing gas supply unit 44. The acetic acid anhydride gas diffused in the diffusion space 61j is supplied through the discharge holes 61k into the chamber 61 or the chamber main body 61a.

In the heat treatment apparatus 60 having the above configuration, first, when the wafer W is transferred into the chamber 61 through the loading/unloading port 61c by using a transfer unit (not shown), the supporting pins 61i are moved up to be protruded from the upper surface of the mounting table 61h, and receive the wafer W from the transfer unit. Then, the supporting pins 42i are moved down to be immersed inside the mounting table 61h such that the wafer W is mounted on the mounting table 61h. Further, when the transfer unit (not shown) is retracted from the chamber 61, the loading/unloading port 61c is closed by the shutter 61d.

When the wafer W is mounted on the mounting table 61h and the loading/unloading port 61c is closed, an acetic acid anhydride gas is supplied into the chamber 61 from the processing gas supply unit 44. The inside of the chamber 61 is maintained under an atmosphere of an acetic acid anhydride gas having a low oxygen density (for example, 50 ppm or less). Then, each wafer W is heated while the temperature of the heater 62 is set to be a specific temperature of, for example, 200˜400° C. Accordingly, since the coating film such as a low-k film or a hard mask film formed on the wafer W is hardened in an atmosphere almost free of oxygen, degradation is prevented. Further, oxidation of a metal film formed on the wafer W is also prevented. When oxide exists on the surface of the metal film, the oxide is removed. Further, acetic acid anhydride or products such as water and carbon dioxide produced by a reduction reaction of acetic acid anhydride are discharged through the discharge port 611 out of the chamber 61.

When the wafer W is completely heated by the heater 62, the supply of an acetic acid anhydride gas using the processing gas supply unit 44 is stopped. Further, while the supporting pins 61i are moved up to receive the wafer W from the mounting table 61h, the loading/unloading port 61c is opened by the shutter 61d and the transfer unit (not shown) receives the wafer W from the supporting pins 61i to transfer the wafer W to the outside of the chamber 61 through the loading/unloading port 61c.

The heat treatment apparatus 60 may be provided in the processing unit set 13 or 14 in the wafer processing system 100 shown in FIG. 1. Accordingly, the heat treatment in the heat treatment apparatus 40 becomes unnecessary and the heat treatment unit 4 and the interface station 5 are also unnecessary. Thus, it is possible to reduce a size of the wafer processing system.

Hereinafter, another heat treatment apparatus capable of performing the heat treatment method in accordance with the present invention will be described.

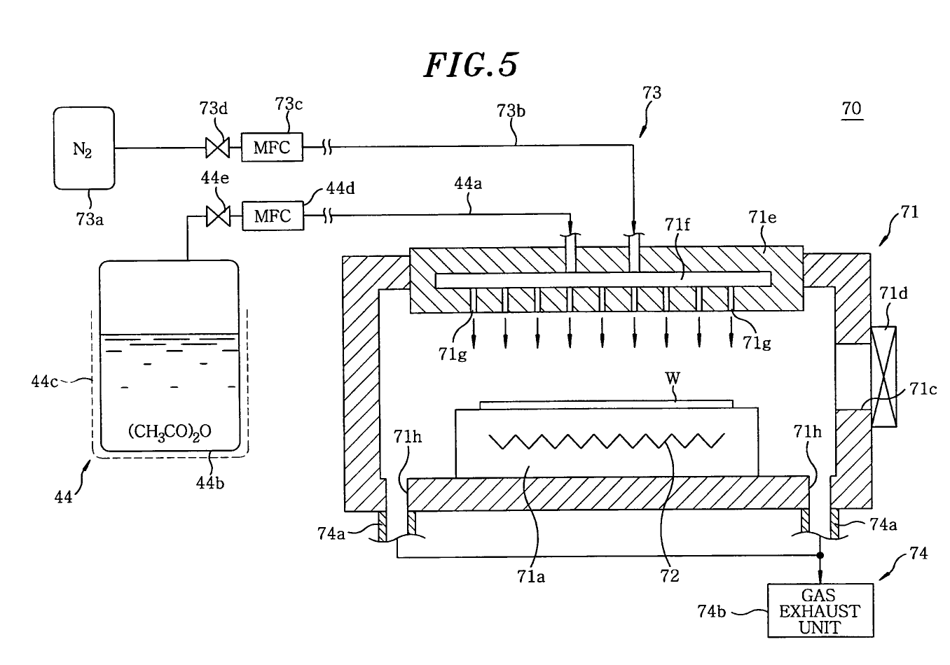

FIG. 5 schematically shows a cross sectional view of still another heat treatment apparatus capable of performing the heat treatment method in accordance with the present invention.

In this embodiment of the present invention, a heat treatment apparatus 70, which performs a heat treatment on the wafer W under a specific depressurized atmosphere, for example, a vacuum atmosphere, is explained. Further, in the heat treatment apparatus 70, the same parts as those of the heat treatment apparatus 60 shown in FIG. 4 are designated by the same reference numerals and the description thereof is omitted. The heat treatment apparatus 70 is used when a low-k film, a hard mask film or the like is formed in a depressurized or vacuum process by employing, for example, a CVD method. The heat treatment apparatus 70 includes a chamber 71 accommodating the wafer W, a processing gas supply unit 44 for supplying an acetic acid anhydride gas into the chamber 71, a nonreactive gas supply unit 73 for supplying a nitrogen gas, serving as a diluent gas for diluting the acetic acid anhydride gas or a nonreactive gas, into the chamber 71, a heater 72 for heating the wafer W in the chamber 71, and a depressurizing device 74 capable of reducing the inner pressure of the chamber 71 to a predetermined pressure, for example, a vacuum pressure. Further, the heat treatment apparatus 70 is also controlled in the same way as the heat treatment apparatuses 40 and 60.

The chamber 71 is formed in an approximately cylindrical or box shape having an upper opening. A susceptor 71a for mounting the wafer W is disposed at a bottom portion of the chamber 71. The heater 72 is embedded in the susceptor 71a to heat the wafer W through the susceptor 71a. A loading/unloading port 71c for loading/unloading the wafer W to/from the chamber 71 and a gate valve 71d for opening and closing the loading/unloading port 71c is formed at the sidewall of the chamber 71.

A shower head 71e is disposed at an upper portion of the chamber 71 to close the opening and face the susceptor 71a. A processing gas supply line 44a of the processing gas supply unit 44 is connected to the shower head 71e. The shower head 71e includes a diffusion space 71f for diffusing the acetic acid anhydride gas supplied from the processing gas supply unit 44 and the nitrogen gas supplied from the nonreactive gas supply unit 73. Further, the shower head 71e includes a plurality of discharge holes 71g formed on its surface facing the susceptor 71a to discharge the acetic acid anhydride gas supplied from the processing gas supply unit 44 and the nitrogen gas supplied from the nonreactive gas supply unit 73 into the chamber 71.

A gas exhaust port 71h is formed in a lower wall of the chamber 71. The depressurizing device 74 includes a gas exhaust pipe 74a connected to the gas exhaust port 71h and a gas exhaust device 74b for compulsorily discharging a gas out of the chamber 71 through the gas exhaust pipe 74a.

The nonreactive gas supply unit 73 includes a nonreactive gas supply source 73a serving as a supply source of a nitrogen gas, a nonreactive gas supply line 73b for supplying the nitrogen gas of the nonreactive gas supply source 73a into the diffusion space 71f of the shower head 71e, and a mass flow controller 73c and a valve 73d serving as a flow rate controller for controlling a flow rate of the nitrogen gas flowing in the nonreactive gas supply line 73b.

In the heat treatment apparatus 70, first, the wafer W is transferred into the chamber 71 through the loading/unloading port 71c by using a transfer unit (not shown) and mounted on the susceptor 71a. The loading/unloading port 71c is closed with the gate valve 71d to seal the inside of the chamber 71. Then, the inner pressure of the chamber 71 is reduced to a predetermined pressure, for example, a vacuum pressure, by using the depressurizing device 74. Further, a nitrogen gas is supplied into the chamber 71 from the nonreactive gas supply unit 73 and an acetic acid anhydride gas is supplied into the chamber 71 from the processing gas supply unit 44. Accordingly, the inside of the chamber 71 is maintained under an atmosphere of an acetic acid anhydride gas and a nitrogen gas having a low oxygen density (for example, 50 ppm or less). In this case, since the inside of the chamber 71 is maintained at a predetermined pressure, for example, a vacuum pressure by using the depressurizing device 74, it is possible to efficiently diffuse the acetic acid anhydride gas in the chamber 71. Further, since the acetic acid anhydride gas in the chamber 71 is diluted with the nitrogen gas, it is possible to prevent corrosion of the chamber 71. Further, the depressurization, the supply of the nitrogen gas, and the supply of the acetic acid anhydride gas may be performed at the same time or alternately at predetermined intervals by the depressurizing device 74, the nonreactive gas supply unit 73 and the processing gas supply unit 44, respectively.

The inside of the chamber 71 is maintained under an atmosphere of an acetic acid anhydride gas having a low oxygen density and a nitrogen gas. Then, the wafer W is heated while the temperature of the heater 72 is set to be a specific temperature of, for example, 200˜400° C. Accordingly, since a coating film such as a low-k film or a hard mask film formed on the wafer W is hardened in an atmosphere almost free of oxygen, degradation is prevented. Further, oxidation of a metal film formed on the wafer W is also prevented. When oxide exists on the surface of the metal film, the oxide is removed. Further, products such as water and carbon dioxide produced by a reduction reaction of acetic acid anhydride are discharged by using the depressurizing device 74.

Once the wafer W is completely heated by the heater 72, the depressurization using the depressurizing device 74, the supply of the nitrogen gas using the nonreactive gas supply unit 73, and the supply of the acetic acid anhydride gas using the processing gas supply unit 44 are stopped. The loading/unloading port 71c is opened by the gate valve 71d, and the wafer W is unloaded from the chamber 71 through the loading/unloading port 71c.

In this embodiment, since the wafer W is heated under an atmosphere of acetic acid anhydride without being exposed to air, it is possible to surely prevent degradation of the low-k film, hard mask film or the like formed on the wafer W.

Further, the present invention is not limited to the above embodiments, and the embodiments can be modified within the scope of the invention. For example, also in a batch type heat treatment apparatus, a substrate may be heated at a vacuum pressure. Further, a well-known reducing gas such as hydrogen or ammonia, water vapor or the like in addition to a nonreactive gas such as a nitrogen gas may be used as a gas added with a processing gas such as acetic acid anhydride. If a small amount of an added gas, small enough not to cause oxidation of the low-k film or metal film, is supplied, an oxidizing gas such as oxygen, ozone and N₂O may be used.

### INDUSTRIAL APPLICABILITY

The present invention may be applied to a baking process performed at a high temperature or low temperature before a hardening process performed on a resin film such as a low-k film or a hard mask film, an aging process using a sol-gel method or the like by appropriately setting a heating temperature without being limited to a hardening process performed on a resin film such as a low-k film or a hard mask film and/or a heat treatment performed on a metal film.

What is claimed is:

1. A heat treatment method comprising:
placing a substrate having an interlayer insulating film of a low dielectric constant (low-k film) and/or a metal film in a processing chamber;
supplying the processing chamber with a reducing gaseous organic compound containing at least one of carboxylic acid anhydride, ester, organic acid ammonium salt, organic acid amine salt, organic acid amide, organic acid hydrazide, organic acid metal complex, and organic acid metal salt while controlling its flow rate; and
heating the substrate in the processing chamber supplied with the gaseous organic compound.

2. The heat treatment method of claim 1, wherein the metal film contains copper (Cu).

3. A heat treatment apparatus for performing a heat treatment on a substrate having an interlayer insulating film of a low dielectric constant (low-k film) and/or a metal film, the heat treatment apparatus comprising:
a processing chamber for accommodating a substrate therein;
an organic compound supply unit for supplying the processing chamber with a reducing gaseous organic compound containing at least one of carboxylic acid anhydride, ester, organic acid ammonium salt, organic acid amine salt, organic acid amide, organic acid hydrazide, organic acid metal complex, and organic acid metal salt while controlling its flow rate; and
a heating unit for heating the substrate in the processing chamber,
wherein the substrate is heated in the processing chamber in a state where the reducing gaseous organic compound is supplied to the processing chamber.

4. A storage medium which is operated on a computer and stores a program for controlling a heat treatment apparatus, wherein the program controls the heat treatment apparatus to perform a heat treatment method including:
placing a substrate having an interlayer insulating film of a low dielectric constant (low-k film) and/or a metal film in a processing chamber;
supplying the processing chamber with a reducing gaseous organic compound containing at least one of carboxylic acid anhydride, ester, organic acid ammonium salt, organic acid amine salt, organic acid amide, organic acid hydrazide, organic acid metal complex, and organic acid metal salt while controlling its flow rate; and
heating the substrate in the processing chamber supplied with the gaseous organic compound.
